(19) United States
(12) Patent Application Publication
(10) Pub. No.: US 2008/0160667 A1
(43) Pub. Date: Jul. 3, 2008

(54) FABRICATING METHOD OF IMAGE SENSOR

(76) Inventor: Sang-Gi Lee, Gyeongi-do (KR)

Correspondence Address: SHERR & NOURSE, PLLC, 620 HERNDON PARKWAY, SUITE 200, HERNDON, VA, 20170, US

(21) Appl. No.: 11/957,180

(22) Filed: Dec. 14, 2007

(30) Foreign Application Priority Data
Dec. 27, 2006 (KR) 10-2006-0134450

(51) Int. Cl. H01L 21/02

(52) U.S. Cl. 438/73; 257/E21.002

(57) ABSTRACT

A fabricating method of an image sensor that can include steps of forming a first isolation area and a first alignment key in a semiconductor substrate using a first mask pattern as a mask; and then forming a first photodiode in the semiconductor substrate using a second mask pattern as a mask.

The present application claims priority under 35 U.S.C. 119 and 35 U.S.C. 365 to Korean Patent Application No. 10-2006-0134450 (filed on Dec. 27, 2006), which is hereby incorporated by reference in its entirety.

### BACKGROUND

An image sensor is a semiconductor device for converting an image into an electrical signal. An image sensor may be classified as a charge coupled device (CCD) sensor or a complementary metal-oxide semiconductor (CMOS) image sensor. The CCD sensor may include a plurality of MOS capacitors which operate by moving carriers generated by way of light. A CMOS image sensor may include a plurality of unit pixels and a CMOS logic circuit controlling the output signals of the unit pixels.

An image sensor may have a substrate, a plurality of photodiodes including a red photodiode, a green photodiode and a blue photodiode, a plurality of plugs for transferring electric signals generated in each photodiode to the surface of the semiconductor substrate, and a transistor for transferring the electric signals. In such an image sensor, isolation between unit pixels may be important. Impurities for electrical isolation between the pixels may be implanted by applying a pattern process so that an isolation area may be formed in the semiconductor substrate.

### SUMMARY

Embodiments relate to a fabricating method of an image sensor that can include forming an isolation area between photodiodes and an alignment key using one mask.

Embodiments relate to a fabricating method of an image sensor that can reduce the overall number of processes for forming an isolation area between photodiodes by using one mask and then, forming an alignment key using the same mask.

Embodiments relate to a fabricating method of an image sensor that can include at least one of the following steps: forming a first isolation area and a first alignment key in a semiconductor substrate using a first mask pattern as a mask; and then forming a first photodiode in the semiconductor substrate using a second mask pattern as a mask.

Embodiments relate to a fabricating method of an image sensor that can include at least one of the following steps: forming a first mask pattern over a semiconductor substrate, the first mask pattern having a first opening and a second opening; forming an isolation area in the semiconductor substrate at the first opening using the first mask pattern as a mask; forming an alignment key in the semiconductor in the second opening using the first mask pattern as a mask; removing the first mask pattern; forming a second mask pattern over the semiconductor substrate including the isolation area; and then forming a first photodiode using the second mask pattern as a mask and removing the second mask pattern.

Embodiments relate to a fabricating method of an image sensor that can include at least one of the following steps: forming a first isolation area and a first alignment key in a semiconductor substrate using a first mask pattern as a mask and then removing the first mask pattern; forming a first photodiode in the semiconductor substrate using a second mask pattern as a mask and removing the second mask pattern; forming a first epitaxial layer over the semiconductor substrate; forming a second isolation area and a second alignment key in the first epitaxial layer using a third mask pattern as a mask and then removing the third mask pattern; forming a second photodiode in the first epitaxial layer using a fourth mask pattern as a mask and then removing the fourth mask pattern; forming a second epitaxial layer over the first epitaxial layer; forming a third isolation area and a third alignment key in the second epitaxial layer using a fifth mask pattern as a mask and then removing the fifth mask pattern; and then forming a third photodiode in the second epitaxial layer using a sixth mask pattern as a mask.

### DRAWINGS

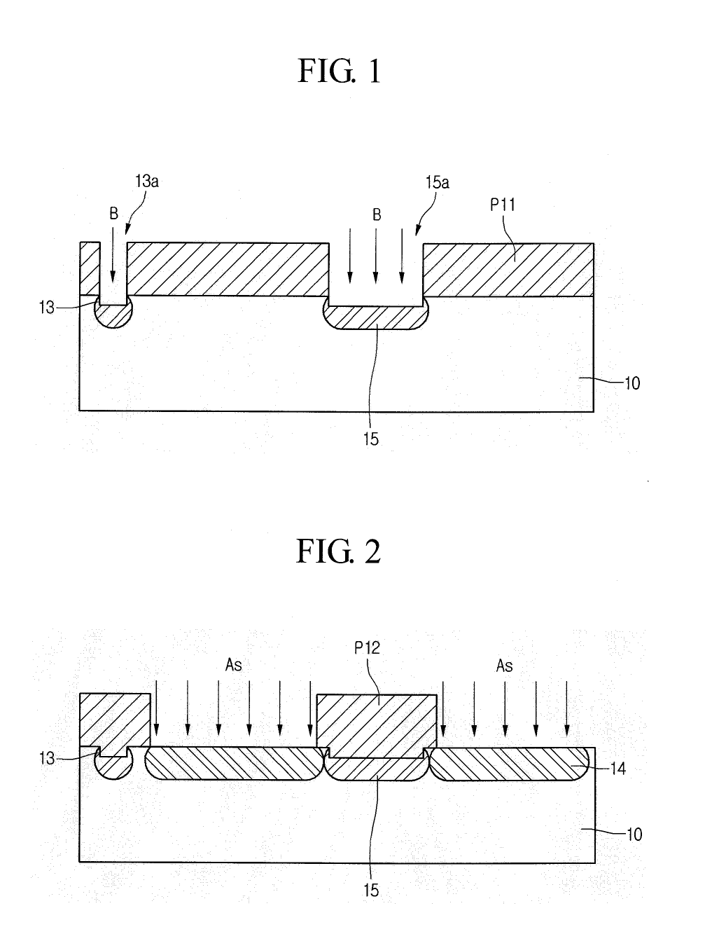

Example FIGS. 1 to 4 illustrate a fabricating method of an image sensor, in accordance with embodiments.

### DESCRIPTION

Also, in the description of the embodiment, when each layer (film), an area, a pattern or structures are described to be formed “on/above/over/upper” or “down/below/under/lower” each layer (film), the area, the pattern or the structures, it can be understood as the case that each layer (film), an area, a pattern or structures are formed by being directly contacted to each layer (film), the area, the pattern or the structures and it can further be understood as the case that other layer (film), other area, other pattern or other structures are additionally formed therebetween. Therefore, the meanings should be judged according to the technical idea of the embodiment.

As illustrated in example FIG. 1, in order to form first alignment key 13 and first isolation area 15 prior to forming a first photodiode, first photoresist pattern P11 can be formed on and/or over semiconductor substrate 10. First photoresist pattern P11 may include first opening 13a and second opening 15a formed therein. First opening 13a and second opening 15a can be formed in an area where first alignment key 13 and first isolation area 15 are formed, respectively.

First photoresist pattern P11 can be formed by using a mask for forming the alignment key to expose a first isolation area and an alignment key area. First isolation area 15 can then be formed in the first isolation area of semiconductor substrate 10 by implanting impurity ions such as boron (B) into semiconductor substrate 10 using first photoresist pattern P11 as a mask prior. An etching process can then be performed to form first align key 13. First photoresist pattern P11 can then be removed. Accordingly, two processes for forming the first isolation area 15 and the first alignment key 13 can simultaneously be performed through one pattern process using one mask.

In the etching process, an etched portion is formed in the first isolation area 15. But, the etched portion has a little effect on isolation quality of the first isolation area 15.

As illustrated in example FIG. 2, second photoresist pattern P12 for forming red photodiode 14 can then be formed on and/or over semiconductor substrate 10. Second photoresist pattern P12 is formed on and/or over first isolation area 15. A first photodiode such as red photodiode 14 can then be formed by implanting impurity ions such as arsenic (As) using second photoresist pattern P12 as a mask. Second photoresist P12 may then be removed.

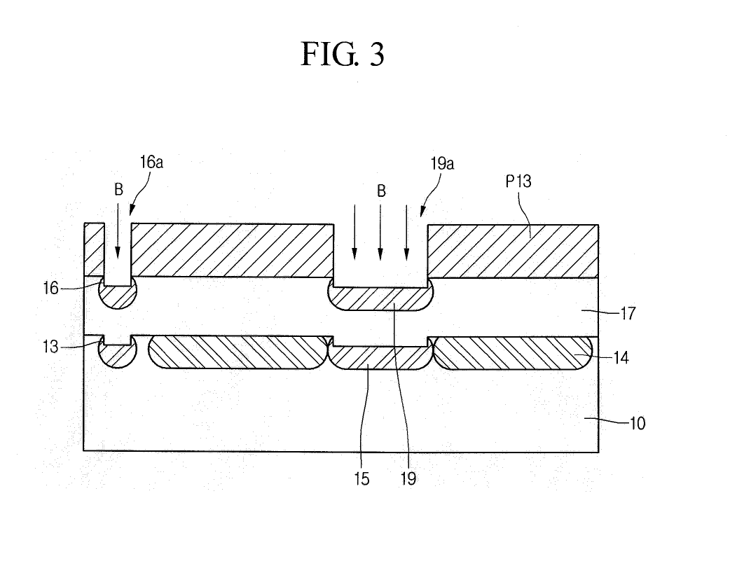

As illustrated in example FIG. 3, epitaxial layer 17 can then be formed by growing the surface of semiconductor substrate 10 in which red photodiode 14 is formed. Third photoresist pattern P13 for forming second align key 16 and second isolation area 19 can then be formed. Third photoresist pattern P13 may include third opening 16a and fourth opening 19a formed therein. Third opening 16a and fourth opening 19a can be formed in an area where second alignment key 16 and second isolation area 19 are formed, respectively.

Third photoresist pattern P13 can be formed by using a mask for forming the second alignment key 16 to expose the second isolation area 19 together with the second alignment key area 16.

The second isolation area 19 can then be formed by implanting impurity ions such as boron (B) into epitaxial layer 17 using third photo resist pattern P13 as a mask. An etching process can then be performed to form second align key 16. Third photoresist pattern P13 can then be removed. Accordingly, two process for forming the second isolation area 19 and the second alignment key 16 can simultaneously be performed through one pattern processing using one mask.

In the etching process, an etched portion is formed in the second isolation area 19. But, the etched portion has a little effect on isolation quality of the second isolation area 19.

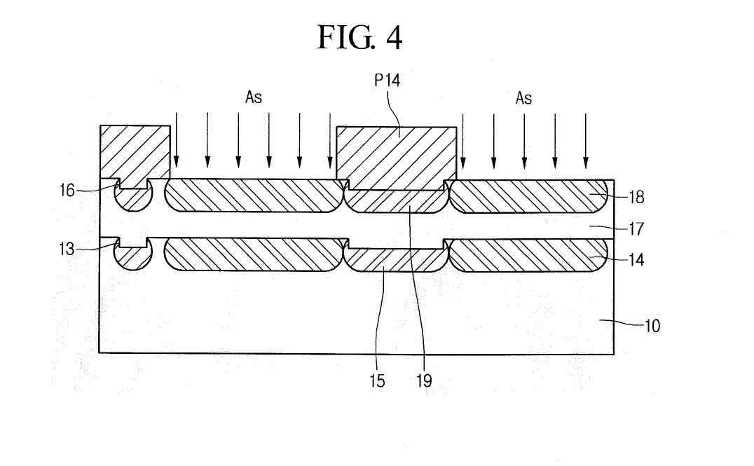

As illustrated in example FIG. 4, fourth photoresist pattern P14 for forming a second photodiode such as green photodiode 18 can then be formed on and/or over epitaxial layer 17. Fourth photoresist pattern P14 can then be formed on and/or over second isolation area 19. Green photodiode 18 can then be formed by implanting impurity ions such as arsenic (As) using fourth photoresist pattern P14 as a mask.

Next, after another epitaxial layer is formed by growing another epitaxial layer, processes forming a third photodiode such as a blue photodiode can then be performed to fabricate a vertical image sensor.

In accordance with embodiments, although an existing mask is used, the number of pattern processes can be reduced so that a fabricating process of the image sensor can be simplified, fabrication costs thereof can be reduced, and isolation characteristics thereof can be improved.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a first mask pattern over a semiconductor substrate, the first mask pattern having a first opening and a second opening;
forming an isolation area in the semiconductor substrate at the first opening using the first mask pattern as a mask;
forming an alignment key in the semiconductor in the second opening using the first mask pattern as a mask;
removing the first mask pattern;
forming a second mask pattern over the semiconductor substrate including the isolation area; and then forming a first photodiode using the second mask pattern as a mask and removing the second mask pattern.

2. The method of claim 1, wherein the first photodiode comprises any one of a red photodiode and a green photodiode.

3. The method of claim 1, further comprising forming a second photodiode after forming the first photodiode.

4. The method of claim 3, wherein forming the second photodiode comprises:
forming an first epitaxial layer over the semiconductor substrate;
forming a third mask pattern over the first epitaxial layer, the third mask pattern having a third opening and a fourth opening;
forming a second isolation area in the first epitaxial layer at the third opening using the third mask pattern as a mask;
forming a second alignment key in the first epitaxial layer at the fourth opening using the third mask pattern as a mask;
removing the third mask pattern;
forming a fourth mask pattern over the first epitaxial layer including the second isolation area; and then
forming the second photodiode using the fourth mask pattern as a mask and removing the second mask pattern.

5. The method of claim 4, wherein the second photodiode comprises any one of a red photodiode and a green photodiode.

6. The method of claim 5, further comprising forming a third photodiode after forming the second photodiode.

7. The method of claim 6, wherein forming the third photodiode comprises:
forming a second epitaxial layer over the first epitaxial layer;
forming a fifth mask pattern over the second epitaxial layer, the fifth mask pattern having a fifth opening and a sixth opening;
forming a third isolation area in the second epitaxial layer at the fifth opening using the fifth mask pattern as a mask;
forming a third alignment key in the second epitaxial layer at the sixth opening using the fifth mask pattern as a mask;
removing the fifth mask pattern;
forming a sixth mask pattern over the second epitaxial layer including the third isolation area; and then
forming the third photodiode using the sixth mask pattern as a mask.

8. The method of claim 7, wherein the third photodiode comprises a blue photodiode.

9. The method of claim 1, wherein the first mask pattern comprises a photoresist pattern.

10. The method of claim 1, wherein forming the first isolation area comprises implanting impurities using the first mask pattern as a mask.

11. The method of claim 10, wherein the impurities comprises boron.

12. The method of claim 1, wherein forming the first alignment key comprises etching the semiconductor substrate using the first mask pattern as a mask.

13. The method of claim 1, wherein forming the first photodiode comprises implanting impurities in the semiconductor substrate using the second mask pattern as a mask.

14. The method of claim 13, wherein the impurities comprises arsenic.

15. A method comprising:
forming a first isolation area and a first alignment key in a semiconductor substrate using a first mask pattern as a mask and then removing the first mask pattern;
forming a first photodiode in the semiconductor substrate using a second mask pattern as a mask and removing the second mask pattern;
forming a first epitaxial layer over the semiconductor substrate;
forming a second isolation area and a second alignment key in the first epitaxial layer using a third mask pattern as a mask and then removing the third mask pattern;
forming a second photodiode in the first epitaxial layer using a fourth mask pattern as a mask and then removing the fourth mask pattern;
forming a second epitaxial layer over the first epitaxial layer;
forming a third isolation area and a third alignment key in the second epitaxial layer using a fifth mask pattern as a mask and then removing the fifth mask pattern; and then
forming a third photodiode in the second epitaxial layer using a sixth mask pattern as a mask.

16. The method of claim 15, wherein the first mask pattern, the second mask pattern, the third mask pattern, the fourth mask pattern, the fifth mask pattern and the sixth mask pattern each comprise a photoresist pattern.

17. The method of claim 15, wherein the first photodiode, the second photodiode and the third photodiode are each composed of an arsenic material.

18. The method of claim 17, wherein the first photodiode comprises a red photodiode, the second photodiode comprises a green photodiode and the third photodiode comprises a blue photodiode.

19. The method of claim 15, wherein the first isolation area, the second isolation area and the third isolation area are each composed of boron material.

20. A method comprising:
forming a first isolation area and a first alignment key in a semiconductor substrate using a first mask pattern as a mask; and then forming a first photodiode in the semiconductor substrate using a second mask pattern as a mask.
